(19) United States
(12) Patent Application Publication
(10) Pub. No.: US 2026/0089847 A1
(43) Pub. Date: Mar. 26, 2026

(54) BONDING HEAD AND BONDING APPARATUS INCLUDING THE SAME

(71) Applicant: Samsung Display Co., LTD., Yongin-si (KR)

(72) Inventors: JAESEONG LEE, Yongin-si (KR); YONGAN LEE, Yongin-si (KR); DAEHO YANG, Yongin-si (KR); BUMKU YOON, Yongin-si (KR)

(21) Appl. No.: 19/212,877

(22) Filed: May 20, 2025

(30) Foreign Application Priority Data
Sep. 25, 2024 (KR) 10-2024-0129761

(51) Int. Cl. H05K 3/30; B30B 15/00; B30B 15/06

(52) U.S. Cl. CPC H05K 3/305; B30B 15/0052; B30B 15/064; H05K 2203/0195; H05K 2203/1105

(57) ABSTRACT

A bonding head includes a first frame, a second frame, a first linear transfer unit, a third frame, a second linear transfer unit, and a head unit. The first linear transfer unit may move the second frame relative to the first frame in a third direction. The second linear transfer unit may move the third frame relative to the second frame in a second direction. The head unit may be coupled to the third frame. A first distance from a first centerline of the first linear transfer unit to a first end of the second frame in the first direction may be greater than a second distance from the first centerline of the first linear transfer unit to a second end of the second frame in the first direction.

This application claims priority to Korean Patent Application No. 10-2024-0129761, filed on Sep. 25, 2024, and all the benefits accruing therefrom under 35 U.S.C. § 119, the content of which in its entirety is herein incorporated by reference.

### BACKGROUND

### 1. Field

The disclosure relates to a bonding head, and more particularly, to a bonding head which applies pressure to attach two electronic components to each other and a bonding apparatus including the same.

### 2. Description of the Related Art

Electronic devices such as smartphones, digital cameras, notebook computers, navigation systems, and smart televisions that provide images to users include display devices for presenting such images.

Display devices generate images and deliver the generated images to users through a display screen.

The display panel of the display device may include a liquid crystal display panel, an organic light-emitting display panel, or the like.

A driving chip that provides various control signals and supply voltages is attached to the display panel via a module process.

Techniques for attaching the driving chip to the display panel are generally categorized into chip-on-glass (“COG”) mounting and chip-on-film (“COF”) mounting. Of these techniques, the COF mounting technique involves mounting the driving chip onto a film and then attaching the film to the display panel.

The display panel is provided with a pad portion to which the COF is attached, and the pad portion may include a plurality of pads. The pad portion may be provided in plural, depending on the size of the display panel. Accordingly, a bonding process for attaching the COF to each of the pad portions may be performed.

### SUMMARY

Embodiments of the disclosure provide a bonding head which applies pressure to attach two electronic components to each other and improve the efficiency of the bonding process, as well as a bonding apparatus including the same.

A bonding head in an embodiment of the disclosure includes a first frame, a second frame, a first linear transfer unit, a third frame, a second linear transfer unit, and a head unit. The first frame includes a first top plate extending in a first direction and a second direction that intersect each other. The second frame includes a second top plate facing a lower surface of the first top plate and a side plate extending downward from a front end of the second top plate in the first direction and being perpendicular to the first direction. The first linear transfer unit is coupled to the first and second top plates and moves the second frame relative to the first frame in a third direction intersecting the first and second directions. The third frame is disposed on an inner surface of the side plate and overlaps the second top plate in the third direction. The second linear transfer unit is disposed on the inner surface of the side plate and moves the third frame relative to the second frame in the second direction. The head unit is disposed on below the second frame and is coupled to the third frame. The second frame includes a first end, which defines the front end in the first direction, and a second end, which defines a rear end in the first direction. A first distance from a first centerline of the first linear transfer unit to the first end of the second frame in the first direction is greater than a second distance from the first centerline of the first linear transfer unit to the second end of the second frame in the first direction.

In an embodiment, the bonding head may further include a first linear guide unit. The first linear guide unit may guide the second frame for movement in the third direction. The first frame may further include a first rear plate extending downward from a front end of the first top plate in the second direction. The second frame may further include a second rear plate extending downward from a front end of the second top plate in the second direction. The first linear guide unit may include a first guide rail and a first guide block, the first guide rail being coupled to one of the first rear plate and the second rear plate, and the first guide block being attached to the other of the first rear plate and the second rear plate and slidably coupled to the first guide rail.

In an embodiment, the first linear transfer unit may include a servo motor coupled to the first top plate and a ball screw coupled to the second top plate.

In an embodiment, the bonding head may further include a cylinder. The cylinder may be coupled to the third frame and apply downward pressure on the head unit.

In an embodiment, an extended line of a second centerline of the cylinder may fully overlap the first centerline in the second direction.

In an embodiment, the bonding head may further include a second linear guide unit. The second linear guide unit may guide the third frame for movement in the second direction. The third frame may include a first vertical plate and a second vertical plate, the first and second vertical plates facing the side plate and spaced apart from each other in the second direction, and a first horizontal plate connecting the first and second vertical plates and extending from the first vertical plate in a direction opposite to the first direction. The second linear guide unit may be coupled to the side plate, the first vertical plate, and the second vertical plate. The cylinder may be coupled to the first horizontal plate.

In an embodiment, the cylinder may overlap the first vertical plate and the second vertical plate in the second direction.

In an embodiment, the cylinder may be disposed between the first vertical plate and the second vertical plate in the second direction.

In an embodiment, the third frame may further include a second horizontal plate connecting the first and second vertical plates and extending from the first vertical plate in the first direction. The second linear transfer unit may be coupled to the side plate and the second horizontal plate.

In an embodiment, the second linear transfer unit may include a linear motor.

In an embodiment, the second linear guide unit may include a second guide rail coupled to the side plate and disposed above the second linear transfer unit, a third guide rail coupled to the side plate and disposed below the second linear transfer unit, a second guide block coupled to the first vertical plate and slidably coupled to the second guide rail, a third guide block coupled to the second vertical plate and slidably coupled to the second guide rail, and a fourth guide block coupled to the first vertical plate and slidably coupled to the third guide rail.

In an embodiment, the bonding head may further include a rotary driving unit. The rotary driving unit may rotate the head unit with reference to a rotational axis in the third direction. The third frame may further include a bottom plate connected to lower ends of the first vertical plate and the second vertical plate. The rotary driving unit may be coupled to the bottom plate.

In an embodiment, the bottom plate and the rotary driving unit may be disposed below the second frame.

In an embodiment, the head unit may include a heater.

In an embodiment, vacuum suction holes which generate negative pressure may be provided in a lower portion of the head unit.

A bonding head in an embodiment of the disclosure includes a first frame, a second frame, a first linear transfer unit, a third frame, a second linear transfer unit, a head unit, a cylinder, and a second linear guide unit. The first frame includes a first top plate extending in a first direction and a second direction that intersect each other. The second frame includes a second top plate facing a lower surface of the first top plate and a side plate extending downward from a front end of the second top plate in the first direction and being perpendicular to the first direction. The first linear transfer unit is coupled to the first and second top plates and moves the second frame relative to the first frame in a third direction intersecting the first and second directions. The third frame is disposed on an inner surface of the side plate and overlaps the second top plate in the third direction. The second linear transfer unit is disposed on the inner surface of the side plate and moves the third frame relative to the second frame in the second direction. The head unit is disposed below the third frame and is coupled to the third frame. The cylinder is coupled to the third frame and applies downward pressure on the head unit. The second linear guide unit guides the third frame for movement in the second direction. The third frame includes a first vertical plate and a second vertical plate, the first and second vertical plates facing the side plate and spaced apart from each other in the second direction, and a first horizontal plate connecting the first and second vertical plates and extending from the first vertical plate in a direction opposite to the first direction. The second linear guide unit is coupled to the side plate, the first vertical plate, and the second vertical plate. The cylinder is coupled to the first horizontal plate and is disposed between the first vertical plate and the second vertical plate in the second direction.

A bonding apparatus in an embodiment of the disclosure includes a main body frame, bonding heads, and a third linear transfer unit. The bonding heads is disposed on the main body frame with equal pitches in the first direction. The third linear transfer unit moves each of the bonding heads relative to the main body frame in the first direction. Each of the bonding heads includes a first frame, a second frame, a first linear transfer unit, a third frame, a second linear transfer unit, and a head unit. The first frame includes a first top plate extending in the first direction and a second direction intersecting the first direction. The second frame includes a second top plate facing a lower surface of the first top plate and a side plate extending downward from a front end of the second top plate in the first direction and being perpendicular to the first direction. The first linear transfer unit is coupled to the first and second top plates and moves the second frame relative to the first frame in a third direction intersecting the first and second directions. The third frame is disposed on an inner surface of the side plate and overlaps the second top plate in the third direction. The second linear transfer unit is disposed on the inner surface of the side plate and moves the third frame relative to the second frame in the second direction. The head unit is disposed below the third frame and is coupled to the third frame. The second frame includes a first end, which defines the front end in the first direction, and a second end, which defines a rear end in the first direction. A first distance from a first centerline of the first linear transfer unit to the first end of the second frame in the first direction is greater than a second distance from the first centerline of the first linear transfer unit to the second end of the second frame in the first direction.

In an embodiment of the disclosure, the bonding heads may include at least three or more bonding heads.

In an embodiment, the pitch may be smaller than the width of each of the bonding heads in the first direction.

In an embodiment, each of the bonding heads may further include a cylinder. The cylinder may be coupled to the third frame and apply downward pressure on the head unit. An extended line of a second centerline of the cylinder may fully overlap the first centerline in the second direction.

By embodiments of the disclosure, three or more bonding heads may be arranged at a pitch smaller than the width of each of the bonding heads in the first direction, enabling three or more second electronic components to be attached simultaneously to a first electronic component.

As a result, it is possible to improve the efficiency of the bonding process.

### BRIEF DESCRIPTION OF THE DRAWINGS

These and/or other features will become apparent and more readily appreciated from the following description of the embodiments, taken in conjunction with the accompanying drawings in which:

FIG. 1 is a diagram illustrating an embodiment of an electronic device to which embodiments of the disclosure may be applied;

FIG. 2 is an exploded view of portion A shown in FIG. 1;

FIG. 3 is a cross-sectional view taken along line I-I shown in FIG. 1;

FIG. 4 is a front view illustrating an embodiment of a bonding head according to the disclosure;

FIG. 5 is a left side view of the bonding head shown in FIG. 4;

FIG. 6 is a cross-sectional view taken along line II-II shown in FIG. 5;

FIGS. 7 and 8 are diagrams illustrating the bonding head of FIGS. 4 and 5, respectively, with the first frame separated;

FIGS. 9 and 10 are diagrams illustrating the bonding head of FIGS. 4 and 5, respectively, with the second frame separated;

FIGS. 11 and 12 are exploded views of the second frame and the third frame shown in FIGS. 9 and 10, respectively;

FIG. 13 is a front view illustrating an embodiment of a bonding apparatus according to the disclosure; and

FIGS. 14 to 16 are diagrams illustrating a bonding process performed by the bonding apparatus shown in FIG. 13.

### DETAILED DESCRIPTION

References will now be made in detail to illustrative embodiments, of which examples are illustrated in the accompanying drawings, where like reference numerals refer to like elements throughout. The embodiments may have a variety of forms and permutations, but the disclosure shall by no means be construed as being limited to the described embodiments. Rather, the disclosure shall be construed to encompass all forms, permutations, equivalents and substitutes covered by the technical ideas and scope of the disclosure. Accordingly, the embodiments are merely described below, by referring to the drawing figures, to explain features of the disclosure.

Like or identical reference numerals refer to like or identical elements. Moreover, in the accompanying drawings, the thicknesses, ratios, and dimensions of the elements may not be to exact scale and may have been exaggerated for the benefit of effective explanation of the technical features associated with these elements. As such, the disclosure shall not be restricted to the thicknesses, ratios, dimensions, etc. illustrated in the drawings.

When an element is described to be “disposed on,” “placed on,” “arranged on,” “connected to,” or “coupled to” another element, it shall be construed as being disposed on, placed on, arranged on, connected to, or coupled to the other element directly but also as possibly having another element therebetween. When one element is described to be “directly disposed on,” “directly placed on,” “directly arranged on,” “directly connected to,” or “directly coupled to” another element, it shall be construed that there is no other element interposed therebetween.

Moreover, relative terms, such as “below,” “under,” “beneath,” “lower,” “bottom,” “above,” “over,” “upper,” “top,” etc., may be used herein to describe one element's relationship to another element as illustrated in the accompanying drawing figures. It shall be understood that relative terms are intended to encompass different orientations of the device in addition to the orientation depicted in the accompanying drawing figures. When the device in one of the drawing figures is turned over, elements described as being on the “lower” side of the other elements would then be oriented on “upper” sides of the other elements. The exemplary term “lower” may therefore encompass an orientation of both “lower” and “upper,” depending on the particular orientation of the figure. Similarly, if the device in one of the drawing figures is turned over, elements described as “below” or “beneath” other elements would then be oriented “above” the other elements. The exemplary term “below” or “beneath” may therefore encompass an orientation of both above and below.

Furthermore, when one device or layer is described to be “on,” “over,” “above,” and the like, another device or layer, it shall also encompass the case of yet another device or layer disposed on, over, above, and the like, the other device or layer or interposed between the one device or layer and the other device or layer. On the contrary, when one device or layer is described to be “directly on,” “directly over,” “directly above,” and the like, another device or layer, it shall mean that no other device or layer is interposed between the one device or layer and the other device or layer.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Unless otherwise defined, all terms, including technical terms and scientific terms, used herein have the same meaning as how they are generally understood by those of ordinary skill in the art to which the disclosure pertains. Any term that is defined in a general dictionary shall be construed to have the same meaning in the context of the relevant art, and, unless otherwise defined explicitly, shall not be interpreted to have an idealistic or excessively formalistic meaning.

Terms such as “first” and “second” may be used in describing various elements, but the above elements shall not be restricted to the above terms. The above terms may be used only to distinguish one element from the other. For instance, the first element may be named the second element, and vice versa, without departing the scope of claims of the present disclosure. Unless clearly used otherwise, any expressions in a singular form may include a meaning of a plural form. The term “and/or” shall include the combination of a plurality of listed items or any of the plurality of listed items.

In an embodiment of the disclosure, directions labeled as first to third directions DR1 to DR3 may be defined. The first direction DR1 may be parallel to one side of a display panel DP. The second direction DR2 may intersect the first direction DR1 and may be parallel to another side of the display panel DP. The third direction DR3 may be perpendicular to one surface of the display panel DP. In an embodiment of the disclosure, the phrase “in a plan view” refers to viewing along the third direction DR3.

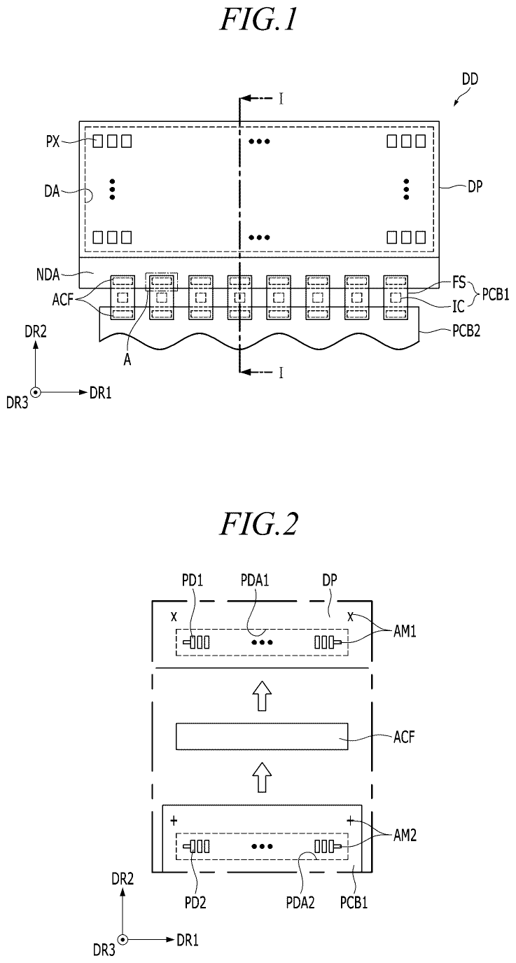

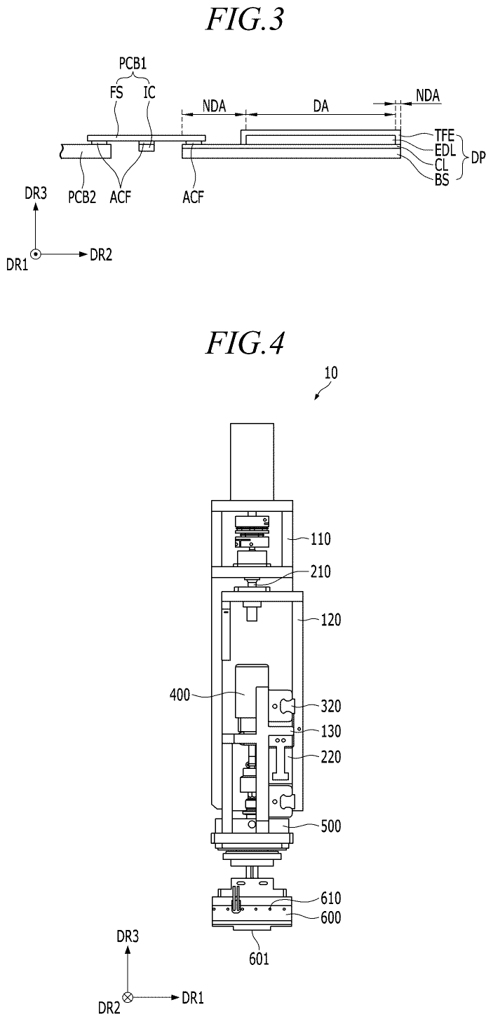

FIG. 1 illustrates an embodiment of an electronic device to which embodiments of the disclosure may be applied. FIG. 2 is an exploded view of portion A in FIG. 1, and FIG. 3 is a cross-sectional view taken along line I-I in FIG. 1.

Referring to FIG. 1, the electronic device may be a display device DD which generates and display images. The display device DD may include, but not limited to, large-scale devices such as televisions, notebook computers, monitors, or billboards. In an embodiment, the display device DD may also be used as the display device for various products, including mobile phones, smartphones, tablet personal computers (“tablet PCs”), smartwatches, watch phones, portable communication terminals, electronic notepads, e-books, portable multimedia players (“PMPs”), navigation systems, ultra-mobile PCs (“UMPCs”), and internet-of-things (“IoT”) devices.

The display device DD may be any one of an organic light-emitting display device, a liquid crystal display device, a plasma display device, a field emission display device, an electrophoretic display device, an electrowetting display device, a quantum dot display device, and a micro-light-emitting diode (“LED”) display device. Hereinafter, the display device DD is described as an organic light-emitting display device, but the disclosure is not limited to what is described herein.

The electronic device may include a first electronic component, second electronic components, and a third electronic component. The first electronic component may be a display panel DP, the second electronic components may be first circuit boards PCB1, and the third electronic component may be a second circuit board PCB2. However, the disclosure is not limited to these examples.

The display panel DP may include a display area DA and a non-display area NDA defined therein. The display area DA refers to the region where images are displayed, while the non-display area NDA is a peripheral region surrounding the display area DA and does not display images.

The non-display area NDA may include a mounting region where the first circuit board PCB1 is attached. In the illustrated embodiment, the display area DA is illustrated as having a quadrangular shape, e.g., rectangular shape, and the non-display area NDA is depicted as surrounding the display area DA. However, the shapes of the display area DA and the non-display area NDA may be designed in various forms and are not limited to the illustrated configuration.

Arranged within the display area DA may be pixels PX which implement images. Each of the pixels PX may include a light-emitting diode and a pixel circuit which controls the driving of the light-emitting diode. The light-emitting diode may be an organic light-emitting diode, and the pixel circuit may include a thin-film transistor. However, the disclosure is not limited to these configurations.

The pixels PX may be arranged in the display area DA in a predetermined repetitive array pattern. In an embodiment, the pixels PX may be arranged in configurations such as a Pentile™ array, a stripe array, or a diamond Pixel™ array, for example.

Signal lines connected to the pixels PX may be disposed in the non-display area NDA. The signal lines may include a data line which is connected to a source electrode of the thin-film transistor and provides a data signal, a gate line which is connected to a gate electrode of the thin-film transistor and provides a gate signal, and a power line which is connected to the light-emitting diode and applies a voltage.

Referring to FIGS. 1 to 3, the display panel DP may include a base substrate BS, a circuit layer CL, a display element layer EDL, and an encapsulation layer TFE. The base substrate BS may be a member that provides a base surface on which the circuit layer CL is disposed. The base substrate BS may include materials such as glass, ceramics, metals, or polymer resins like polyimide. However, the base substrate BS is not limited to these materials and may be an inorganic layer, an organic layers, or a composite material layer, which may be formed as a single layer or multiple layers.

The circuit layer CL may be disposed on the base substrate BS and may include pixel circuits and signal lines. The pixel circuits may include pixel transistors which drive light-emitting diodes. The circuit layer CL may also include peripheral transistors which are disposed in the non-display area NDA and output signals for controlling the pixel transistors of the pixel circuits.

The display element layer EDL may be disposed on the circuit layer CL and may include the light-emitting diodes and a pixel defining layer. Each of the light-emitting diodes may include a first electrode, a hole function layer, a light-emitting layer, an electron function layer, and a second electrode. The pixel defining layer may be disposed on the circuit layer CL and may be disposed to cover areas between the first electrodes in a plan view. The pixel defining layer may correspond to non-light-emitting areas and define the light-emitting areas.

The encapsulation layer TFE may be disposed on the display element layer EDL and may protect the light-emitting diodes of the display element layer EDL from moisture, oxygen, and/or foreign substances. The encapsulation layer TFE may include a glass substrate or a synthetic resin substrate. However, the encapsulation layer is not limited to these materials and may also have a laminated structure of an inorganic layer, an organic layer, and an inorganic layer.

The display panel DP may be provided with first pad sections PDA1. The first pad sections PDA1 may be disposed in the non-display area NDA and may be spaced apart from each other in the first direction DR1. Each of the first pad sections PDA1 may include first pads PD1 disposed therein, and the display panel DP may include first alignment marks AM1 corresponding, respectively, to the first pad sections PDA1. The first pads PD1 may be connected to the signal lines of the display panel DP.

The first circuit boards PCB1 may connect the display panel DP and the second circuit board PCB2. In the illustrated embodiment, there are eight first circuit boards PCB1 illustrated, but the number is not limited to this example. Each of the first circuit boards PCB1 may include a flexible substrate FS and a driver chip IC. The driver chip IC may be disposed (e.g., mounted) on the flexible substrate FS. In other words, each of the first circuit boards PCB1 may have a chip-on-film (“COF”) structure, but the disclosure is not limited to this configuration.

The flexible substrate FS may be provided with a second pad section PDA2. The second pad section PDA2 may include second pads PD2 disposed therein. The second pads PD2 may be connected to connection lines provided on the flexible substrate FS. The connection lines may connect the second pads PD2 to the driver chip IC. Additionally, the connection lines may connect the driver chip IC to third pads (not shown) provided on the flexible substrate FS.

The second pads PD2 of the flexible substrate FS may be connected to the first pads PD1 of the display panel DP, and the third pads of the flexible substrate FS may be connected to fourth pads (not shown) provided on the second circuit board PCB2. As a result, the driver chip IC and the second circuit board PCB2 may be electrically connected to the display panel DP, to provide data signals, gate signals, power voltages, etc.

The driver chip IC may be attached to the flexible substrate FS via an adhesive layer ACF. The display panel DP and the second circuit board PCB2 may each be attached to the flexible substrate FS via adhesive layers ACF. The adhesive layer ACF may be an anisotropic conductive film. The adhesive layer ACF may fully overlap the first pad section PDA1 and the second pad section PDA2 in a plan view.

The flexible substrate FS may include second alignment marks AM2. The first alignment marks AM1 of the display panel DP and the second alignment marks AM2 of the flexible substrate FS may be utilized for alignment during the bonding process in which the first circuit board PCB1 is attached to the display panel DP.

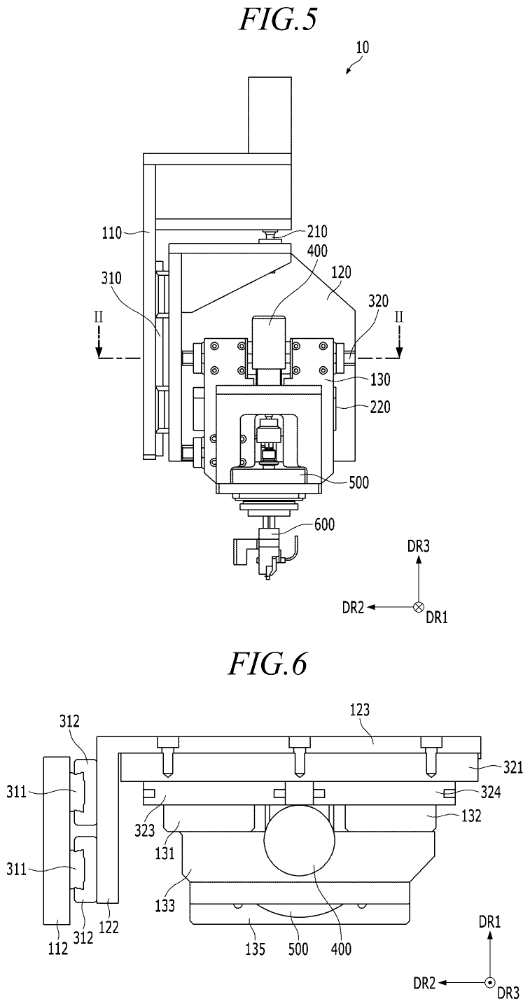

FIG. 4 is a front view illustrating an embodiment of a bonding head 10 according to the disclosure, FIG. 5 is a left-side view of the bonding head 10 shown in FIG. 4, and FIG. 6 is a cross-sectional view taken along line II-II shown in FIG. 5.

The bonding head 10 in an embodiment of the disclosure is a device that may be used in a bonding process to attach the second electronic components to the first electronic component in the manufacturing process of the electronic device described with reference to FIGS. 1 to 3. However, the use of the bonding head 10 is not limited to this.

In the illustrated embodiment, the first to third directions DR1 to DR3 may be defined as described above or as follows. The first direction DR1 may be a direction intersecting the second direction DR2 and the third direction DR3. The second direction DR2 may be the direction of transport by the second linear transfer unit 220. The third direction DR3 may be the direction of transport by the first linear transfer unit 210.

Referring to FIGS. 4 to 6, the bonding head 10 may include a first frame 110, a second frame 120, a third frame 130, a first linear transfer unit 210, a second linear transfer unit 220, a first linear guide unit 310, a second linear guide unit 320, a cylinder 400, a rotary driving unit 500, and a head unit 600. However, the bonding head 10 is not limited to these components, and some of the above-mentioned components may be omitted.

The first frame 110 may be coupled to a main body frame of the bonding apparatus. The second frame 120 may be coupled to the first frame 110 via the first linear transfer unit 210. The third frame 130 may be coupled to the second frame 120 via the second linear transfer unit 220.

The first linear transfer unit 210 may be coupled to the first frame 110 and the second frame 120 and may move the second frame 120 forward and backward in the third direction DR3 relative to the first frame 110. The second linear transfer unit 220 may be coupled to the second frame 120 and the third frame 130 and may move the third frame 130 forward and backward in the second direction DR2 relative to the second frame 120.

The first linear guide unit 310 may be coupled to the first frame 110 and the second frame 120 and may guide the linear movement of the second frame 120 in the third direction DR3. The second linear guide unit 320 may be coupled to the second frame 120 and the third frame 130 and may guide the linear movement of the third frame 130 in the second direction DR2.

The cylinder 400 may be coupled to the third frame 130 and may apply downward pressure to the head unit 600. Specifically, the cylinder 400 may press the head unit 600 in the direction opposite to the third direction DR3. In the specification, unless otherwise specified, the terms “upward” and “downward” are defined based on the orientation shown in the drawings. The cylinder 400 may be, but not limited to, a pneumatic cylinder.

The rotary driving unit 500 may be coupled to the third frame 130 and may rotate the head unit 600 with reference to a rotational axis in the third direction DR3. The rotary driving unit 500 may be, but not limited to, a direct driving motor.

The head unit 600 may be coupled to the third frame 130 via the rotary driving unit 500. The head unit 600 may move forward and backward relative to the rotary driving unit 500 in the third direction DR3. In an embodiment, the head unit 600 may include a guide master coupled to the rotary driving unit 500, for example. The head unit 600 may be provided with a heater 610. Vacuum suction holes 601 which generate negative pressure may be defined in the lower portion of the head unit 600. The vacuum suction holes 601 may be connected to a vacuum pump that provides the negative pressure.

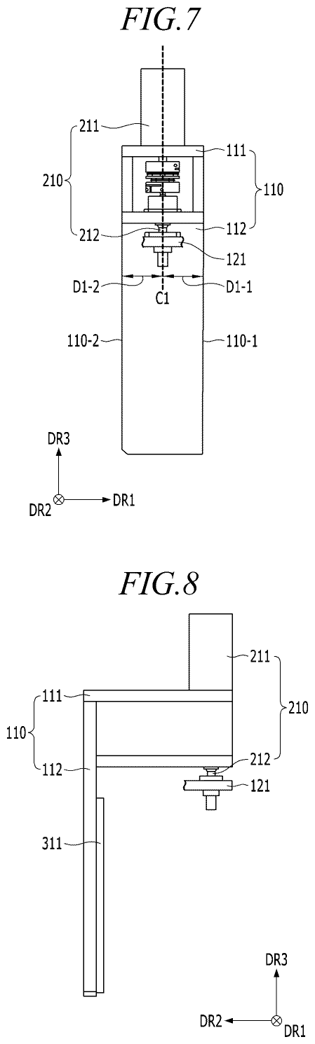

FIGS. 7 and 8 illustrate the first frame separated from the bonding head shown in FIGS. 4 and 5, respectively.

Referring to FIGS. 7 and 8, the first frame 110 may include a first top plate 111 and a first rear plate 112. The first top plate 111 may extend in the first direction DR1 and the second direction DR2 and may be perpendicular to the third direction DR3. The first rear plate 112 may extend downward from a front end of the first top plate 111 in the second direction DR2. The first rear plate 112 may extend in the first direction DR1 and the third direction DR3 and may be perpendicular to the second direction DR2.

The first linear transfer unit 210 may include, as a non-limiting example, a servo motor 211 and a ball screw 212.

The servo motor 211 may be coupled to the first top plate 111 of the first frame 110. The ball screw 212 may be coupled to the second top plate 121 of the second frame 120 and may be connected to the drive shaft of the servo motor 211 through a coupling. As a result, the rotational force provided by the servo motor 211 may be transmitted to the second frame 120 through the ball screw 212.

A first distance D1-1 from a first centerline C1 of the first linear transfer unit 210 to a first end 110-1 of the first frame 110 in the first direction DR1 may be equal to a second distance D1-2 from the first centerline C1 of the first linear transfer unit 210 to a second end 110-2 of the first frame 110 in the first direction DR1. Here, the first centerline C1 of the first linear transfer unit 210 may refer to an imaginary line that passes through the center of the first linear transfer unit 210 and extends in the third direction DR3.

The first end 110-1 of the first frame 110 may be a front end of the first frame 110 in the first direction DR1, and the second end 110-2 of the first frame 110 may be a rear end of the first frame 110 in the first direction DR1. The first end 110-1 of the first frame 110 may include a front surface of the first top plate 111 and a front surface of the first rear plate 112 in the first direction DR1. The second end 110-2 of the first frame 110 may include a rear surface of the first top plate 111 and a rear surface of the first rear plate 112 in the first direction DR1.

The first frame 110 may be aligned in such a way that the first centerline C1 passes through the center of the first frame 110 when viewed from the second direction DR2. In an embodiment, the first frame 110 may be symmetrically formed with reference to the first centerline C1 when viewed from the second direction DR2, for example.

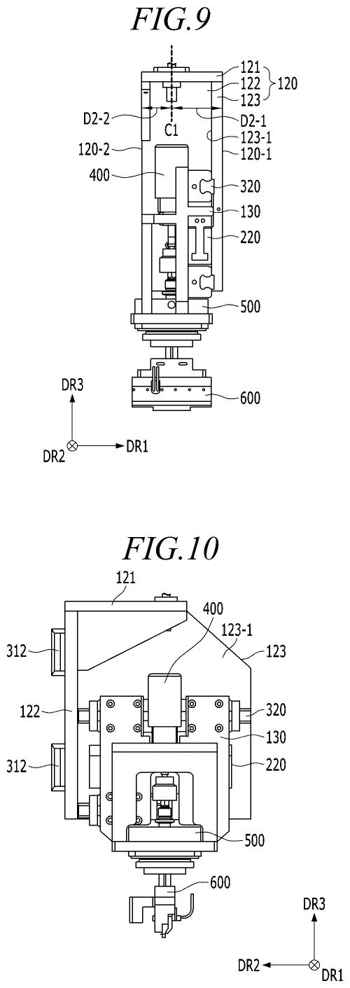

FIGS. 9 and 10 illustrate the second frame separated from the bonding head shown in FIGS. 4 and 5, respectively.

Referring to FIGS. 9 and 10, the second frame 120 may include a second top plate 121, a second rear plate 122, and a side plate 123. The second top plate 121 may be disposed to face the first top plate 111 of the first frame 110. The second top plate 121 may extend in the first direction DR1 and the second direction DR2 and may be perpendicular to the third direction DR3.

The second rear plate 122 may be disposed to face the first rear plate 112 of the first frame 110. The second rear plate 122 may extend downward from a front end of the second top plate 121 in the second direction DR2. The second rear plate 122 may extend in the first direction DR1 and the third direction DR3 and may be perpendicular to the second direction DR2.

The side plate 123 may extend downward from a front end of the second top plate 121 in the first direction DR1. The side plate 123 may extend in the second direction DR2 and the third direction DR3 and may be perpendicular to the first direction DR1.

A first distance D2-1 from the first centerline C1 of the first linear transfer unit 210 to a first end 120-1 of the second frame 120 in the first direction DR1 may be greater than a second distance D2-2 from the first centerline C1 of the first linear transfer unit 210 to a second end 120-2 of the second frame 120 in the first direction DR1.

The first end 120-1 of the second frame 120 may be a front end of the second frame 120 in the first direction DR1, and the second end 120-2 of the second frame 120 may be a rear end of the second frame 120 in the first direction DR1. The first end 120-1 of the second frame 120 may include an outer surface of the side plate 123. The second end 120-2 of the second frame 120 may include a rear surface of the second top plate 121 in the first direction DR1 and a rear surface of the second rear plate 122 in the first direction DR1.

The second frame 120 may be disposed to be offset in the first direction DR1 with respect to the first centerline C1 when viewed from the second direction DR2.

As a result, the first end 120-1 of the second frame 120, or an extended line of the first end 120-1 in the third direction DR3, may not overlap the first frame 110, when viewed from the second direction DR2, but may be spaced apart in the first direction DR1 from the first end 110-1 of the first frame 110. This arrangement allows for an installation space of the second linear transfer unit 220 and the second linear guide unit 320 between the first centerline C1 and the first end 120-1 of the second frame 120.

Additionally, the second end 120-2 of the second frame 120, or an extended line of the second end 120-2 in the third direction DR3, may be disposed between extended lines of the first end 110-1 and the second end 110-2 of the first frame 110 in the third direction DR3 when viewed from the second direction DR2. Accordingly, a gap may be formed between the extended line of the second end 120-2 of the second frame 120 in the third direction DR3 and the extended line of the second end 110-2 of the first frame 110 in the third direction DR3 when viewed from the second direction DR2.

As a result, when arranging the bonding heads 10 side by side in the first direction DR1, by arranging the second frame 120 of one bonding head 10 to overlap with the first frame 110 of a neighboring (adjacent) bonding head 10 when viewed from the second direction DR2, three or more bonding heads 10 may be arranged with a pitch smaller than the width of each of the bonding heads 10.

As a result, three or more second electronic components may be attached to a first electronic component simultaneously, thereby improving the efficiency of the bonding process.

Referring to FIGS. 6, 8, and 10, the first linear guide unit 310 may include a first guide rail 311 and a first guide block 312. The first guide rail 311 may be coupled to the first rear plate 112 of the first frame 110 and may extend in the third direction DR3. The first guide block 312 may be coupled to the second rear plate 122 of the second frame 120 and may be movably coupled to the first guide rail 311, enabling forward and backward movement in the third direction DR3. However, the configuration is not limited to this arrangement. In an alternative embodiment, the first guide rail 311 may be coupled to the second rear plate 122, and the first guide block 312 may be coupled to the first rear plate 112.

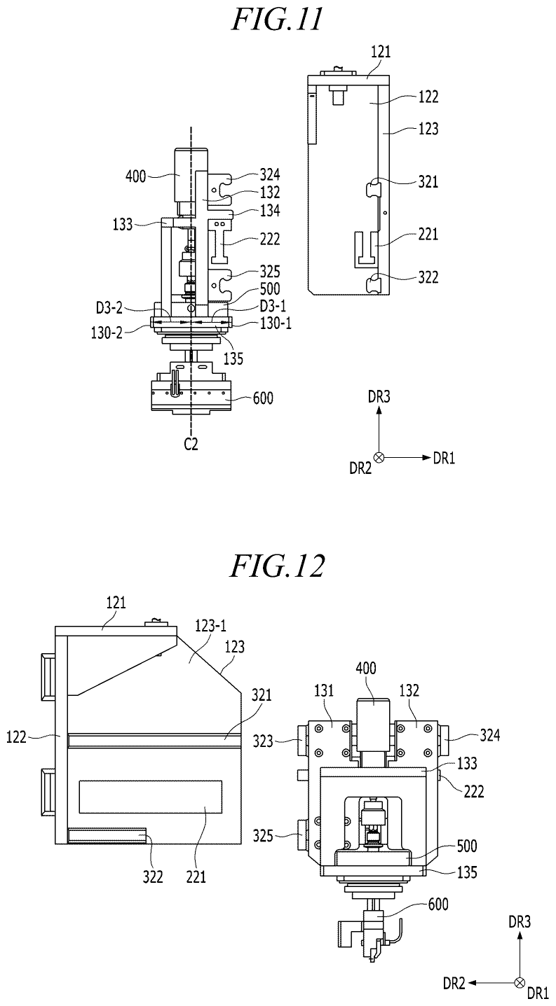

FIGS. 11 and 12 are exploded views of the second frame and the third frame shown in FIGS. 9 and 10, respectively.

Referring to FIGS. 6 and 9 through 12, the third frame 130 may be disposed on an inner surface 123-1 of the side plate 123 of the second frame 120. The third frame 130 may overlap the second top plate 121 of the second frame 120 in the third direction DR3 and the second rear plate 122 of the second frame 120 in the second direction DR2.

The third frame 130 may include a first vertical plate 131, a second vertical plate 132, a first horizontal plate 133, a second horizontal plate 134, and a bottom plate 135.

The first vertical plate 131 and the second vertical plate 132 may be disposed to face the side plate 123 of the second frame 120 and may be spaced apart from each other in the second direction DR2. The first vertical plate 131 may extend in the second direction DR2 and the third direction DR3 and may be perpendicular to the first direction DR1. The second vertical plate 132 may extend in the second direction DR2 and the third direction DR3 and may also be perpendicular to the first direction DR1.

The first horizontal plate 133 may connect the first vertical plate 131 and the second vertical plate 132 and may extend in the direction opposite to the first direction DR1 from the first and second vertical plates 131, 132. The first horizontal plate 133 may extend in the first direction DR1 and the second direction DR2 and may be perpendicular to the third direction DR3.

The second horizontal plate 134 may connect the first vertical plate 131 and the second vertical plate 132 and may extend in the first direction DR1 from the first and second vertical plates 131, 132. The second horizontal plate 134 may extend in the first direction DR1 and the second direction DR2 and may be perpendicular to the third direction DR3.

When viewed from the second direction DR2, the first horizontal plate 133 and the second horizontal plate 134 may be disposed between the first end 120-1 of the second frame 120 or the extended line of the first end 120-1 in the third direction DR3 and the second end 120-2 of the second frame 120 or the extended line of the second end 120-2 in the third direction DR3.

The bottom plate 135 may be connected to lower ends of the first vertical plate 131 and the second vertical plate 132. The bottom plate 135 may extend in the first direction DR1 and the second direction DR2 and may be perpendicular to the third direction DR3.

A first distance D3-1 from the first centerline C1 of the first linear transfer unit 210 to a first end 130-1 of the third frame 130 in the first direction DR1 may be equal to a second distance D3-2 from the first centerline C1 of the first linear transfer unit 210 to a second end 130-2 of the third frame 130 in the first direction DR1. Although the first distance D3-1 and the second distance D3-2 are depicted in the drawings as being measured with reference to the second centerline C2 of the cylinder 400, the first distance D3-1 and the second distance D3-2 may be deemed as being measured with respect to the first centerline C1 when the first centerline C1 completely overlaps with the extended line of the second centerline C2 in the second direction DR2.

The first end 130-1 of the third frame 130 may be a front end of the third frame 130 in the first direction DR1, and the second end 130-2 of the third frame 130 may be a rear end of the third frame 130 in the first direction DR1. The first end 130-1 of the third frame 130 may include a front surface of the bottom plate 135 in the first direction DR1. The second end 130-2 of the third frame 130 may include a rear surface of the bottom plate 135 in the first direction DR1.

The third frame 130 may be aligned in such a way that the extended line of the first centerline C1 passes through the center of the third frame 130 when viewed from the second direction DR2.

The second linear transfer unit 220 may be disposed on the inner surface 123-1 of the side plate 123 of the second frame 120. The second linear transfer unit 220 may be coupled to the side plate 123 of the second frame 120 and the second horizontal plate 134 of the third frame 130.

As a non-limiting example, the second linear transfer unit 220 may include a linear motor. A magnet portion 221 of the linear motor may be coupled to the side plate 123 of the second frame 120, and a motor portion 222 of the linear motor may be coupled to the second horizontal plate 134 of the third frame 130.

When viewed from the second direction DR2, the second linear transfer unit 220 may be disposed between the first end 120-1 of the second frame 120 or the extended line of the first end 120-1 in the third direction DR3 and the second end 120-2 of the second frame 120 or the extended line of the second end 120-2 in the third direction DR3.

The second linear guide unit 320 may be disposed on the inner surface 123-1 of the side plate 123. The second linear guide unit 320 may be coupled to the side plate 123 of the second frame 120 and to the first vertical plate 131 and the second vertical plate 132 of the third frame 130.

The second linear guide unit 320 may include a second guide rail 321, a third guide rail 322, a second guide block 323, a third guide block 324, and a fourth guide block 325. The second guide rail 321 may be coupled to the side plate 123 and disposed above the second linear transfer unit 220, and the third guide rail 322 may be coupled to the side plate 123 and disposed below the second linear transfer unit 220. As a result, the third frame 130 may be stably supported by the second linear guide unit 320.

The second guide block 323 may be coupled to the first vertical plate 131 and coupled to the second guide rail 321 to be slidable forward and backward in the second direction DR2. The third guide block 324 may be coupled to the second vertical plate 132 and coupled to the second guide rail 321 to be slidable forward and backward in the second direction DR2. The fourth guide block 325 may be coupled to the first vertical plate 131 and coupled to the third guide rail 322 to be slidable forward and backward in the second direction DR2.

When viewed from the second direction DR2, the second linear guide unit 320 may be disposed between the first end 120-1 of the second frame 120 or the extended line of the first end 120-1 in the third direction DR3 and the second end 120-2 of the second frame 120 or the extended line of the second end 120-2 in the third direction DR3.

The cylinder 400 may be coupled to the first horizontal plate 133 of the third frame 130, and the extended line of the second centerline C2 of the cylinder 400 may fully overlap the first centerline C1 in the second direction DR2.

Here, the second centerline C2 of the cylinder 400 may refer to an imaginary line that passes through the center of the cylinder 400 and extends in the third direction DR3. The extended line of the second centerline C2 of the cylinder 400 may pass through the center of the head unit 600.

By aligning the extended line of the second centerline C2 of the cylinder 400 to fully overlap the first centerline C1 in the second direction DR2, it becomes possible to minimize structural instability that may be caused by the operation of the first linear transfer unit 210 and/or the cylinder 400.

In an embodiment, when viewed from the second direction DR2, the cylinder 400 may be aligned in such a way that the extended line of the first centerline C1 of the first linear transfer unit 210 passes through the center of the cylinder 400, for example. Additionally, when viewed from the second direction DR2, the head unit 600 may be aligned in such a way that the extended line of the first centerline C1 of the first linear transfer unit 210 passes through the center of the head unit 600.

However, the disclosure is not necessarily limited to the above configuration, and the extended line of the second centerline C2 of the cylinder 400 may not overlap the first centerline C1 in the second direction DR2. In such a case, when viewed from the second direction DR2, the second frame 120 may be aligned in such a way that the extended line of the first centerline C1 of the first linear transfer unit 210 passes through the center of the second frame 120.

The cylinder 400 may be disposed between the first end 120-1 of the second frame 120 or the extended line of the first end 120-1 in the third direction DR3 and the second end 120-2 of the second frame 120 or the extended line of the second end 120-2 in the third direction DR3, when viewed from the second direction DR2.

The cylinder 400 may overlap the first vertical plate 131 and the second vertical plate 132 in the second direction DR2.

As shown in FIG. 6, the cylinder 400 may be disposed between the first vertical plate 131 and the second vertical plate 132 in the second direction DR2. As a result, the width of the second frame 120 in the first direction DR1 may be reduced.

The rotary driving unit 500 may be coupled to the bottom plate 135. The bottom plate 135 and the rotary driving unit 500 may be disposed below the second frame 120. Moreover, the head unit 600 may also be disposed below the second frame 120.

As a result, when bonding heads 10 are arranged in close proximity, it becomes possible to eliminate the possibility of the bottom plate 135, the rotary driving unit 500, or the head unit 600 of one bonding head 10 protruding through the second end 120-2 of the second frame 120 of the one bonding head 10 to interfere with the first end 120-1 of the second frame 120 of a neighboring (adjacent) bonding head 10.

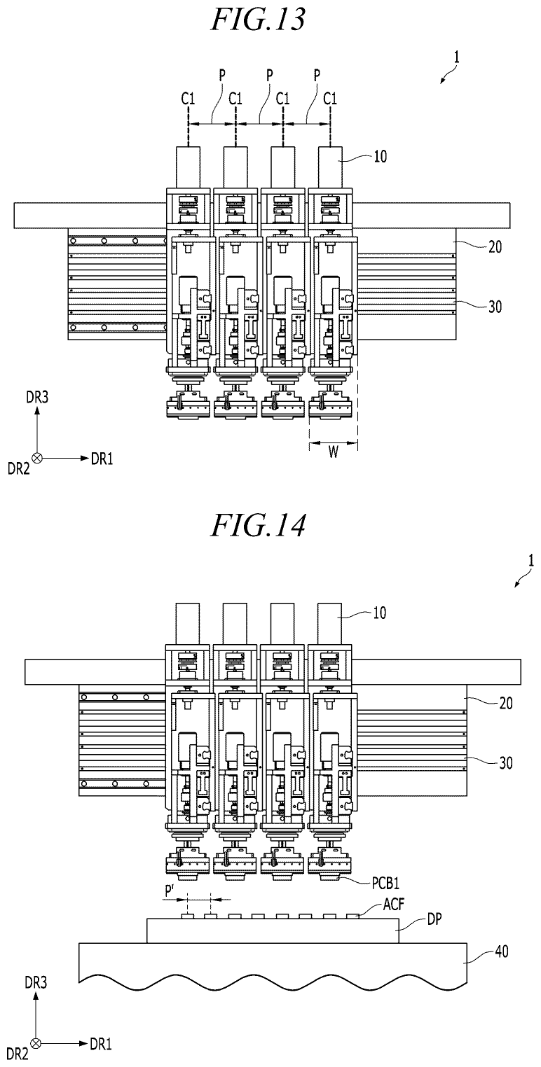

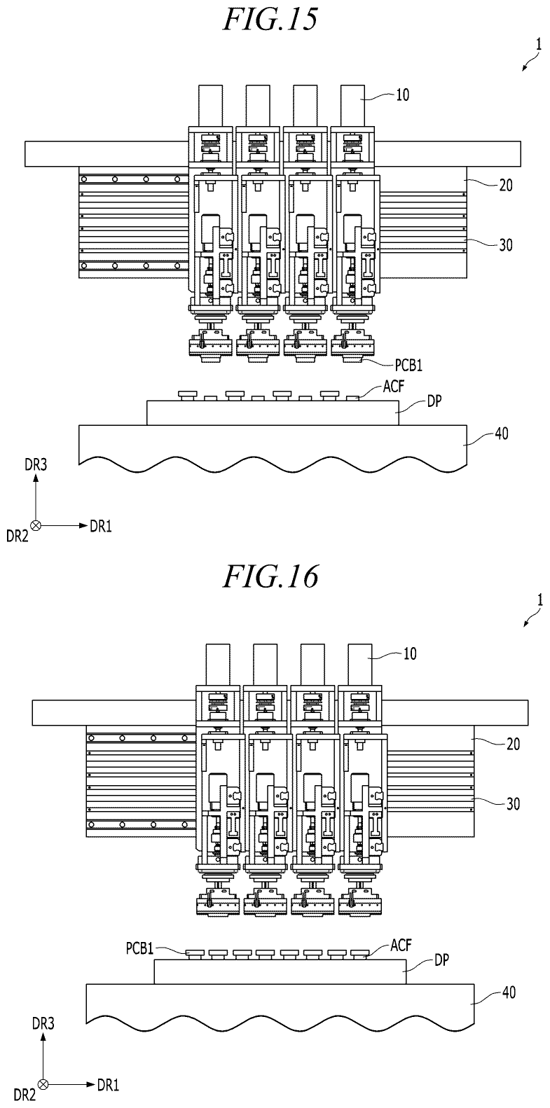

FIG. 13 is a front view illustrating an embodiment of a bonding apparatus 1 according to the disclosure, and FIGS. 14 to 16 illustrate a bonding process performed by the bonding apparatus 1 shown in FIG. 13.

The bonding apparatus 1 in an embodiment of the disclosure may be used in the bonding process to attach the second electronic components to the first electronic component in the manufacturing process of the electronic device described with reference to FIGS. 1 to 3. However, the use of the apparatus is not limited to this application.

Referring to FIG. 13, the bonding apparatus 1 may include bonding heads 10, a main body frame 20, and a third linear transfer unit 30. In the illustrated embodiment, although four bonding heads 10 are illustrated, the number of bonding heads is not limited to four and may be three, five, or more.

Each of the bonding heads 10 may be configured as described with reference to FIGS. 4 to 12. Each of the bonding heads 10 may be coupled to the main body frame 20 via the third linear transfer unit 30.

The third linear transfer unit 30 may move each of the bonding heads 10 forward and backward in the first direction DR1 relative to the main body frame 20. The third linear transfer unit 30 may include, but not limited to, a linear motor.

Each of the bonding heads 10 may be moved by the third linear transfer unit 30 and arranged in the first direction DR1 at equal intervals, referred to as pitch P. Here, the pitch P may refer to the distance between the first centerlines C1 of neighboring (adjacent) bonding heads 10 in the first direction DR1. The pitch P may be smaller than the width W of each of the bonding heads 10 in the first direction DR1.

To achieve this arrangement, in each of the bonding heads 10, the second frame 120 may be disposed off-center in the first direction DR1 relative to the first centerline C1 when viewed from the second direction DR2.

Here, in each of the bonding heads 10, the extended line of the second centerline C2 of the cylinder 400 may completely overlap the first centerline C1 in the second direction DR2.

The widths of the first frame 110, the second frame 120, and the third frame 130 in the first direction DR1 may each be smaller than the width W of each of the bonding heads 10 in the first direction DR1. These widths of the first frame 110, the second frame 120, and the third frame 130 in the first direction DR1 may be equal to one another. In an embodiment, the widths of the first frame 110, the second frame 120, and the third frame 130 in the first direction DR1 may each be 75 millimeters (mm) to 77 mm or 76 mm, while the width W of each of the bonding heads 10 in the first direction DR1 may be 85 mm to 86 mm or 85.5 mm, for example. However, the disclosure is not limited to these dimensions. An embodiment of the bonding process using the bonding apparatus 1 is described below with reference to FIGS. 14 to 16.

First, second electronic components, e.g., the first circuit boards PCB1, may be vacuum-suctioned onto and provided to the head unit 600 of each of the bonding heads 10. The first circuit boards PCB1 may have, but not limited to, a chip-on-film (“COF”) structure.

A first electronic component, e.g., the display panel DP, may be vacuum-suctioned onto a stage 40 of the bonding apparatus 1. The display panel DP may be provided with adhesive layers ACF attached to the first pad sections PDA1.

The bonding heads 10 may be arranged side by side in the first direction DR1 with a pitch P that is twice the pitch P between the first pad sections PDA1. The pitch P may be smaller than the width W of each of the bonding heads 10 in the first direction DR1.

Next, the second linear transfer unit 220 and the rotary driving unit 500 of each of the bonding heads 10 may be controlled to align the first pad sections PDA1 of the display panel DP, arranged in odd-numbered positions, with the second pad sections PDA2 of the first circuit boards PCB1, respectively.

Then, the first linear transfer unit 210 of each of the bonding heads 10 may be controlled to attach the first circuit boards PCB1 to the odd-numbered first pad sections PDA1 of the display panel DP. Here, the head units 600 may be heated by the heater 610.

Subsequently, the first circuit board PCB1 may be vacuum-suctioned onto and provided again to the head unit 600 of each of the bonding heads 10 for a second bonding operation.

The third linear transfer unit 30 may then be controlled to move the bonding heads 10 in the first direction DR1 such that the first circuit boards PCB1 provided again are disposed on the even-numbered first pad sections PDA1 of the display panel DP.

Finally, the first circuit boards PCB1 provided again may be attached onto the even-numbered first pad sections PDA1 of the display panel DP.

In the illustrated embodiment, three or more bonding heads 10 may be disposed with a pitch P smaller than the width of each of the bonding heads 10 in the first direction DR1, allowing three or more second electronic components to be attached simultaneously. As a result, it becomes possible to improve the efficiency of the bonding process.

Hitherto, predetermined preferred embodiments of the disclosure have been described above, but these are merely exemplary and are not intended to limit the disclosure. Those skilled in the art to which the disclosure pertains may make various modifications and changes to the embodiments by adding, changing, deleting, or adding predetermined elements, without departing from the scope of the technical ideas of the disclosure as set forth in the claims, and such modifications and changes should also be regarded as being within the scope of the disclosure.

What is claimed is:

1. A bonding head comprising:
a first frame comprising a first top plate extending in a first direction and a second direction intersecting each other;
a second frame comprising:
a second top plate facing a lower surface of the first top plate and including a front end in the first direction;
a side plate extending downward from the front end of the second top plate in the first direction and perpendicular to the first direction;
a first end which defines the front end in the first direction; and
a second end which defines a rear end in the first direction;
a first linear transfer unit coupled to the first top plate and the second top plate and configured to move the second frame relative to the first frame in a third direction intersecting the first direction and the second direction;
a third frame disposed on an inner surface of the side plate and overlapping the second top plate in the third direction;
a second linear transfer unit disposed on the inner surface of the side plate and configured to move the third frame relative to the second frame in the second direction; and
a head unit disposed below the second frame and coupled to the third frame;
wherein a first distance from a first centerline of the first linear transfer unit to the first end of the second frame in the first direction is greater than a second distance from the first centerline of the first linear transfer unit to the second end of the second frame in the first direction.

2. The bonding head according to claim 1, further comprising a first linear guide unit configured to guide the second frame for movement in the third direction,
wherein the first frame further comprises a first rear plate extending downward from a front end of the first top plate in the second direction,
wherein the second frame further comprises a second rear plate extending downward from a front end of the second top plate in the second direction, and
wherein the first linear guide unit comprises a first guide rail and a first guide block, the first guide rail being coupled to one of the first rear plate and the second rear plate, the first guide block being coupled to a remaining one of the first rear plate and the second rear plate and slidably coupled to the first guide rail.

3. The bonding head according to claim 2, wherein the first linear transfer unit comprises:
a servo motor coupled to the first top plate; and
a ball screw coupled to the second top plate.

4. The bonding head according to claim 1, further comprising a cylinder coupled to the third frame and configured to apply downward pressure to the head unit.

5. The bonding head according to claim 4, wherein an extended line of a second centerline of the cylinder fully overlaps the first centerline in the second direction.

6. The bonding head according to claim 4, further comprising a second linear guide unit configured to guide the third frame for movement in the second direction,
wherein the third frame comprises:
a first vertical plate and a second vertical plate which face the side plate and spaced apart from each other in the second direction; and
a first horizontal plate connecting the first vertical plate and the second vertical plate and extending in a direction opposite to the first direction from the first vertical plate,
wherein the second linear guide unit is coupled to the side plate, the first vertical plate, and the second vertical plate, and
wherein the cylinder is coupled to the first horizontal plate.

7. The bonding head according to claim 6, wherein the cylinder overlaps the first vertical plate and the second vertical plate in the second direction.

8. The bonding head according to claim 6, wherein the cylinder is disposed between the first vertical plate and the second vertical plate in the second direction.

9. The bonding head according to claim 6, wherein the third frame further comprises a second horizontal plate connecting the first vertical plate and the second vertical plate and extending in the first direction from the first vertical plate, and
wherein the second linear transfer unit is coupled to the side plate and the second horizontal plate.

10. The bonding head according to claim 9, wherein the second linear transfer unit comprises a linear motor.

11. The bonding head according to claim 9, wherein the second linear guide unit comprises:
a second guide rail coupled to the side plate and disposed above the second linear transfer unit;
a third guide rail coupled to the side plate and disposed below the second linear transfer unit;
a second guide block coupled to the first vertical plate and slidably coupled to the second guide rail;
a third guide block coupled to the second vertical plate and slidably coupled to the second guide rail; and
a fourth guide block coupled to the first vertical plate and slidably coupled to the third guide rail.

12. The bonding head according to claim 6, further comprising a rotary driving unit configured to rotate the head unit with reference to a rotational axis in the third direction,
wherein the third frame further comprises a bottom plate connected to lower ends of the first vertical plate and the second vertical plate, and
wherein the rotary driving unit is coupled to the bottom plate.

13. The bonding head according to claim 12, wherein the bottom plate and the rotary driving unit are disposed below the second frame.

14. The bonding head according to claim 1, wherein the head unit is provided with a heater.

15. The bonding head according to claim 1, wherein vacuum suction holes configured to generate negative pressure are defined in a lower portion of the head unit.

16. A bonding head comprising:
a first frame comprising a first top plate extending in a first direction and a second direction intersecting each other;
a second frame comprising:
a second top plate facing a lower surface of the first top plate; and
a side plate extending downward from a front end of the second top plate in the first direction and being perpendicular to the first direction;
a first linear transfer unit coupled to the first top plate and the second top plate and configured to move the second frame relative to the first frame in a third direction intersecting the first direction and the second direction;
a third frame disposed on an inner surface of the side plate and overlapping the second top plate in the third direction, the third frame comprising:
a first vertical plate and a second vertical plate which face the side plate and spaced apart from each other in the second direction; and
a first horizontal plate connecting the first vertical plate and the second vertical plate and extending in a direction opposite to the first direction from the first vertical plate;
a second linear transfer unit disposed on the inner surface of the side plate and configured to move the third frame relative to the second frame in the second direction;
a head unit disposed below the third frame and coupled to the third frame;
a cylinder coupled to the third frame and configured to apply downward pressure to the head unit; and
a second linear guide unit configured to guide the third frame for movement in the second direction,
wherein the second linear guide unit is coupled to the side plate, the first vertical plate, and the second vertical plate, and
wherein the cylinder is coupled to the first horizontal plate and disposed between the first vertical plate and the second vertical plate in the second direction.

17. A bonding apparatus comprising:
a main body frame; and
bonding heads arranged on the main body frame at pitches equal to each other in a first direction, each of the bonding heads comprising:
a first frame comprising a first top plate extending in the first direction and a second direction intersecting the first direction;
a second frame comprising:
a second top plate facing a lower surface of the first top plate and including a front end in the first direction;
a side plate extending downward from the front end of the second top plate in the first direction and being perpendicular to the first direction;
a first end which defines the front end in the first direction; and
a second end which defines a rear end in the first direction,
a first linear transfer unit coupled to the first top plate and the second top plate and configured to move the second frame relative to the first frame in a third direction intersecting the first direction and the second direction;
a third frame disposed on an inner surface of the side plate and overlapping the second top plate in the third direction;
a second linear transfer unit disposed on the inner surface of the side plate and configured to move the third frame relative to the second frame in the second direction; and
a head unit disposed below the third frame and coupled to the third frame,
wherein a third linear transfer unit configured to move each of the bonding heads in the first direction relative to the main body frame,
wherein a first distance from a first centerline of the first linear transfer unit to the first end of the second frame in the first direction is greater than a second distance from the first centerline of the first linear transfer unit to the second end of the second frame in the first direction.

18. The bonding apparatus according to claim 17, wherein a number of the bonding heads is three or more.

19. The bonding apparatus according to claim 17, wherein a pitch of the pitches is smaller than a width of each of the bonding heads in the first direction.

20. The bonding apparatus according to claim 17, wherein each of the bonding heads further comprises a cylinder coupled to the third frame and configured to apply downward pressure to the head unit, and
wherein an extended line of a second centerline of the cylinder fully overlaps the first centerline in the second direction.
